(19) United States
(12) Patent Application Publication
(10) Pub. No.: US 2008/0203425 A1
(43) Pub. Date: Aug. 28, 2008

(54) Phototransistors, Methods of Making Phototransistors, and Methods of Detecting Light

(75) Inventor: Oleg Sulima, Newark, DE (US)

Correspondence Address: BURR & BROWN, PO BOX 7068, SYRACUSE, NY, 13261-7068, US

(73) Assignee: ADVANCED OPTICAL MATERIALS, LLC

(21) Appl. No.: 10/586,193

(22) PCT Filed: Jan. 24, 2005
(86) PCT No.: PCT/US2005/002085

§ 371 Date: May 5, 2008

Related U.S. Application Data
(60) Provisional application No. 60/538,483, filed on Jan. 22, 2004.

(51) Int. Cl. H01L 31/0304; H01L 31/11; G01J 1/02

(52) U.S. Cl. 257/185; 257/187; 438/94; 250/338.4; 257/E31.022; 257/E31.069

(57) ABSTRACT

A phototransistor (400) comprises an emitter (43) comprising antimony, a base (42) comprising antimony, and a collector (41) comprising antimony. Preferably, the emitter, the base and the collector each comprises at least one of AlInGaAsSb, AlGaAsSb, AlGaSb, GaSb and InGaAsSb. The base comprises an emitter-contacting portion (41b) with a base-contacting portion (43a) of the emitter. The collector comprises a base-contacting portion (41b) which is in contact with a collector-contacting portion (421a) of the base. The phototransistor produces an internal gain upon being contacted with light within a receivable wavelength range, preferably greater than 1.7 micrometers. Also, a method of detecting light using such a phototransistor.

### CROSS-REFERENCE TO RELATED APPLICATIONS

This application claims the benefit of U.S. Provisional Patent Application Ser. No. 60/538,483, filed Jan. 22, 2004, the entirety of which is incorporated herein by reference.

### FIELD OF THE INVENTION

The present invention relates to phototransistors. In particular, the present invention relates to phototransistors having sensitivity to light at wavelengths greater than 1.8 micrometers, preferably in the range of 1.8 micrometers to 2.5 micrometers.

### BACKGROUND OF THE INVENTION

Photodetectors which are sensitive at wavelengths >1.8 micrometers, in particular >2.0 micrometers, and which exhibit internal gain, are highly desirable.

InGaAs has been studied as a potential material for this application, but to reach sensitivity at wavelengths >1.7 micrometers, so-called extended wavelength InGaAs photodetectors are necessary. Strained InGaAs layers (not lattice matched to InP substrates) are used in these devices, which results in non-optimized device properties, such non-optimized device properties coming from non-optimal materials properties which result from lattice mismatch.

Commercially available extended wavelength InGaAs and HgCdTe detectors are described as providing 2 micrometer sensitivity, but due to the absence of an internal gain mechanism, these detectors lack sufficient responsivity.

There are three general types of semiconductor devices which can provide internal gain: avalanche photodiodes (APD), avalanche photodiodes with separate absorption and multiplication layers (SAM-APD), and phototransistors. InGaAsSb-based APDs and SAM-APDs have been demonstrated, but InGaAsSb-based APDs and SAM-APDs require operation at elevated voltages (greater than 10V in some cases) and very homogenous material. Without providing these properties, avalanching either does not start or proceeds locally, which may cause generation of micro-plasma and irreversible damage to the devices. Moreover, APDs and SAM-APDs are very sensitive to applied voltage. Thus, complicated systems for voltage stabilization are required for their efficient operation.

Unlike APDs and SAI-APDs, phototransistors can operate at much lower voltages. (in the range of 1-4 volts). This is an advantage to the system designer, resulting in a lower cost system. In addition, homogeneity is not as crucial in phototransisters as it is in APDs (as noted above, if there is not sufficient homogeneity in an APD, micro-plasma can be generated, causing irreversible damage).

Phototransistors do require surface passivation, especially in materials systems with strong absorption coefficients, where charge carriers are generated close to the Surface. To passivate surfaces in many materials, the growth of wide bandgap windows is required. Phototransistors perform well when fabricated with high-quality, lattice-matched, epitaxial layers. In many materials systems, however, these layers are very difficult to grow, especially in a commercial setting. To date, no InGaAsSb-based or any other antimonide-based phototransistors (other than ours) have been reported.

It would be highly advantageous to provide phototransistors which are sensitive at wavelengths >1.7 micrometers.

For example, one application for a phototransistor having sensitivity to light of wavelength in the 1.8 to 2.5 micrometer range is in the measurement of atmospheric carbon dioxide. Knowledge of the spatial and temporal distribution of atmospheric carbon dioxide (CO₂) is important for understanding its impact on global warming and climate changes. Recent progress in the development of 2 micrometer tunable lasers, where strong CO₂ absorption lines exist, drives the need for high quality detectors operating at the same wavelength. Such technology would allow the application of high resolution remote sensing techniques such as the Differential Absorption Lidar (DIAL) for profiling and monitoring CO₂ in the atmosphere. An ideal detector for this application would have high quantum efficiency with high gain, low noise and narrow spectral response peaking around the wavelength of interest. This increases the DIAL instrument signal-to-noise ratio while minimizing the background signal, thereby increasing the sensitivity and dynamic range besides reducing its mass and cost for space missions.

Another example of an application for a phototransistor having sensitivity to light of wavelength in the 1.8 to 2.5 micrometer range is in detecting glucose in blood, as glucose has a “fingerprint” in this wavelength range.

Another example is the use of phototranistors in an array to create 2 dimensional images of light in the wavelength range 1.8 to 2.5 microns for temperature sensing and other. applications.

In summary, it would be highly desirable to provide a phototransistor having sensitivity to light at wavelengths >1.8 micrometer, especially at wavelengths of 2.0 micrometers and above.

### SUMMARY OF THE INVENTION

The present invention provides phototransistors having sensitivity to light at wavelengths >1.8 micrometer, especially at wavelengths of 2.0 micrometers and above. The present invention further provides phototransistors having high responsivity, low noise, high internal gain and/or large dynamic range. The word “internal” in the expression “internal gain” indicates that no external amplifiers and thus external gain are involved, and that the gain is provided solely by phototransistors themselves. The word “gain” in the expression “internal gain” is understood as an optical gain, which is the ratio between the number of charge carriers in the collector current and the number of incident photons. High internal gain increases the detectivity of the phototransistors (i.e., the phototransistors are more effective at detecting the presence of light within the wavelength range for which the phototransistor is effective).

Each of the phototransistors according to the present invention comprises an emitter, a base, and a collector, each of which comprises antimony. The emitter, the base and the collector arc preferably arranged in an n-p-n arrangement (i.e., the emitter and collector arc n-doped, while the base is p-doped), although they can alternatively be in a p-n-p arrangement. The base has an emitter-contacting portion which is in contact with a base-contacting portion of the emitter. The base also has a collector-contacting portion which is in contact with a base-contacting portion of the collector. Preferably, the emitter, the base and the collector each comprise at least one of AlInGaAsSb, AlGaAsSb, AlGaSb, GaSb and InGaAsSb. Preferably, at least part of the collector and/or at least part of the base comprises InGaAsSb providing photosensitivity at wavelengths in the range of from 1.8 to 2.5 micrometers, as GaSb, AlGaSb and Al(In)GaAsSb cannot provide bandgap required for such photosensitivity.

The phototransistors according to the present invention preferably further include a substrate on which the collector, base and emitter have been formed. The substrate preferably comprises antimony, and a particularly preferred substrate comprises GaSb. It is further preferred that the antimony-containing substrate, collector, base and emitter are lattice matched in order to provide a high crystal quality. The collector, the base, the emitter and the substrate can be lattice matched by appropriately controlling the compositions employed during the deposition processes used to grow the respective layers on the substrate, in accordance with technology which is well known in the art.

In accordance with a particularly preferred aspect of the present invention, the emitter consists essentially of Al(In)GaAsSb (i.e., AlGaAsSb which optionally contains some In), the base consists essentially of Al(In)GaAsSb and InGaAsSb, the collector consisting essentially of InGaAsSb, the collector, the base and the emitter are preferably sequentially formed., in that order, on a substrate consisting essentially of GaSb or InGaSb, and the substrate, the collector, the base and the emitter are substantially lattice matched. The expression “substantially lattice matched” as used herein in connection with a plurality of layers means that the difference in lattice parameters at room temperature is less than about 10⁻² Ångstrom.

The phototransistors according to the present invention preferably further comprise at least front and back contacts, for electrical connection to the emitter and the collector, respectively. Optionally, a third contact can be provided in contact with the base (although it is not necessary to provide a conductive member in contact with the base in a phototransistor, a phototransistor which has such a contact on the base can exhibit hybrid characteristics that resemble those of a phototransistor as well as a traditional three-contact transistor).

According to a first aspect of the present invention, the base comprises a composite material having a plurality of different bandgap values such that there is an overall bandgap gradient between the emitter-contacting portion of the base and the collector-contacting portion of the base, with the band gap values decreasing as the distance from the emitter-contacting portion of the base increases and the distance from the base collector-contacting portion decreases. In such a phototransistor, the bandgap value of the emitter is preferably larger than the bandgap value of the base at the emitter-contacting portion of the base, to provide a p-n heterojunction at the emitter-base interface, and/or the collector bandgap value is preferably less than the bandgap value of the base at the collector-contacting portion of the base to provide a p-n heterojunction at the base-collector interface.

According to a second aspect of the present invention, the base comprises at least a first base layer and a second base layer, in which the first base layer includes the emitter-contacting portion of the base and comprises a first band gap value, and in which the second base layer includes the collector-contacting portion of the base and comprises a second bandgap value that is less than the first bandgap value. The first and second base layers are in contact across a first-second base layer interface. The first base layer preferably consists essentially of Al(In)GaAsSb, and the second base layer preferably consists essentially of InGaAsSb. Preferably, the first and second base layers provide a p-p heterojunction at the first-second base layer interface due to the difference in their respective bandgaps. Optionally, the emitter can comprise a bandgap value which is larger than the first bandgap value in order to provide a p-n heterojunction at the emitter-base interface, and/or the collector can comprise a bandgap value which is less than the second bandgap value in order to provide a p-n heterojunction at the base-collector interface.

According to a third aspect of the present invention, the emitter-contacting portion of the base comprises a bandgap value which is less than a bandgap value of the base-contacting portion of the emitter in order to provide a p-n heterojunction at the emitter-base interface, and/or the base-contacting portion of the collector comprises a bandgap which is less than a bandgap of the collector-contacting portion of the base in order to provide a heterojunction at the collector-base interface. In this aspect of the present invention, the base preferably has a substantially uniform bandgap, although the bandgap of the base may alternatively vary to some degree.

According to a fourth aspect of the present invention, the emitter-contacting portion of the base comprises a bandgap value which is less than a bandgap value of the base-contacting portion of the emitter in order to provide a p-n heterojunction at the emitter-base interface, and/or the base-contacting portion of the collector comprises a bandgap which is substantially equal to a bandgap of the collector-contacting portion of the base in order to provide a homojunction at the collector-base interface. In this aspect of the present invention, the base preferably has a substantially uniform bandgap, although the bandgap of the base may alternatively vary to some degree.

According to a fifth aspect of the present invention, the emitter-contacting portion of the base comprises a bandgap value which is less than a bandgap value of the base-contacting portion of the emitter in order to provide a p-n heterojunction at the emitter-base interface, and/or the base-contacting portion of the collector comprises a bandgap which is greater than a bandgap of the collector-contacting portion of the base in order to provide a heterojunction at the collector-base interface. In this aspect of the present invention, the base preferably has a substantially uniform bandgap, although the bandgap of the base may alternatively vary to some degree.

The expression “substantially uniform bandgap value” as used herein in connection with a layer or structure means that the bandgap values of not more than about 10% of the regions of the layer or structure exhibit a bandgap value which differs from an average bandgap value of the layer or structure by more than about 5%.

The present invention is also directed to methods of making phototransistors as described above. The collector, the base and the emitter each can be formed by any suitable process or combination of processes, a variety of which are well known to those of skill in the art. The processes for forming the collector, the base and the emitter preferably each comprise at least one process selected from the group consisting of liquid phase epitaxy processes, molecular beam epitaxy processes, and metal-organic chemical vapor deposition processes.

The present invention is also directed to a method of detecting light, comprising contacting a phototransistor as described herein with light comprising at least a first wavelength (the first wavelength falling within the range of receivable wavelength), and applying a current through the phototransistor, the current being amplified as a result of the light contacting the phototransistor. The receivable wavelength ranges of the phototransistors of the present invention preferably encompass at least some infrared radiation wavelengths.

The phototransistors of the present invention may optionally further comprise at least one buffer layer comprising antimony positioned between the substrate and the collector. The phototransistors of the present invention may optionally further comprise at least one contact layer comprising antimony positioned on a side of the emitter which is opposite the base.

### BRIEF DESCRIPTION OF THE DRAWINGS

FIG. 1 is a schematic view of a first embodiment of a phototransistor according to the present invention;

FIG. 2 is a schematic view of a second embodiment of a phototransistor according to the present invention;

FIG. 3 is a schematic view of a third embodiment of a phototransistor according to the present invention; and

FIG. 4 is a schematic view of a fourth embodiment of a phototransistor according to the present invention.

FIG. 5 depicts the device according to the present invention referred to in the Example.

FIG. 6 depicts the experimental setup used in the Example.

FIG. 7 depicts the results of emitter dark current variation with the collector-emitter voltage at different temperatures in the Example.

FIG. 8 depicts responsivity variation with the collector-emitter voltage at different temperatures for two phototransistor samples in the Example.

FIG. 9 depicts responsivity variation with temperature at different collector-emitter voltages for the same samples in the Example.

FIG. 10 depicts detectivity calculations for phototransistors and photodiodes described in the Example.

### DETAILED DESCRIPTION OF THE INVENTION

As mentioned above, phototransistors according to the present invention comprise an emitter, a base and a collector. The base has an emitter-contacting portion which is in contact with a base-contacting portion of the emitter. The base also has a collector-contacting portion which is in contact with a base-contacting portion of the collector.

As a result of the bandgap characteristics of the emitter, base and collector in the various devices according to the present invention, as described in more detail below, at least a portion of radiation striking the front side of the phototransistor (i.e., the side of the phototransistor which is closer to the emitter, the back side being the side of the phototransistor which is closer to the collector) which has energy lower than the bandgap of the emitter passes through the emitter unattenuated, and is then absorbed in the base and/or the collector. As a result, in the case of an n-p-n arrangement, holes are photogenerated in the base where the energy is absorbed, and holes can also be swept into the base from the collector, which increases the forward bias of the junction between the emitter and the base, thereby enabling a large amount of electrons to flow from the emitter to the collector. In the case of a p-n-p arrangement, electrons are photogenerated in the base where the energy is absorbed, and electrons can also be swept into the base from the collector, which increases the forward bias of the junction between the emitter and the base, thereby enabling a large amount of holes to flow from the emitter to the collector.

The emitter in each phototransistor according to the present invention comprises at least one semiconductor layer comprising antimony. Examples of preferred materials out of which the emitter can be constructed include (and are not limited to) quintary or quaternary antimony-containing materials (e.g., AlInGaAsSb, AlGaAsSb, InGaAsSb), AlGaSb, GaSb and combinations thereof, with AlInGaAsSb and AlGaAsSb being the most preferred.

The emitter can have a substantially uniform bandgap value, or the bandgap values in different portions of the emitter can differ from one another. In any event, however, the emitter bandgap value (or the average bandgap value for the emitter) is preferably larger than tie bandgap values (or average bandgap values) for each of the collector and the base. In addition, at least one portion of the base or the collector preferably has a smaller bandgap value than the minimum bandgap value for the emitter.

The emitter preferably has a thickness in a range of from about 50 nanometers to several hundred micrometers, more preferably from about 50 nanometers to about 3 micrometers.

The base in each phototransistor according to the present invention comprises at least one semiconductor layer comprising antimony. Examples of preferred materials out of which the base can be constructed include (and are not limited to) quintary or quaternary antimony-containing materials (e.g., AlInGaAsSb, AlGaAsSb and in GaAsSb), AlGaSb, GaSb, with a combination of Al(In)GaAsSb and InGaAsSb being the most preferred.

The base can have a substantially uniform bandgap value, or the bandgap values in different portions of the base can differ from one another.

The base preferably has a thickness in a range of from about 100 nanometers to about 3 micrometers. Lower thicknesses for the base help to increase speed, while increasing the thickness of the base tends to decrease speed while increasing the absorption of the incident light.

The collector in each phototransistor according to the present invention comprises at least one semiconductor layer comprising antimony. Examples of preferred materials out of which the collector can be constructed include (and are not limited to) quintary or quaternary antimony-containing materials (e.g., AlInGaAsSb, AlGaAsSb and InGaAsSb), AlGaSb, GaSb. A particularly preferred material out of which the collector can be constructed is InGaAsSb.

The collector can have a substantially uniform bandgap value, or the bandgap values in different portions of the collector can differ from one another.

The collector preferably has a thickness in a range of from about 100 nanometers to about 3 micrometers.

As mentioned above, the phototransistors according to the present invention preferably further comprise a substrate, as shown and described below in connection with FIGS. 1-4, for example. The substrate provides a support for the formation of the active layers (i.e., collector, base and emitter), and a lattice structure on which the collector (or the at least one buffer layer, if included) can preferably be epitaxially grown.

The substrate, if provided, comprises antimony. Example of preferred materials out of which the substrate can be constructed include GaSb and InGaSb.

The substrate preferably has a thickness of at least about 100 nanometers, more preferably at least about 250 micrometers.

As mentioned above, the phototransistors according to the present invention can optionally further comprise at least one buffer layer positioned between the substrate and the collector, as shown and described below in connection with FIGS. 3 and 4. The at least one buffer layer can be provided, if needed or desired, to promote high crystal quality of the phototransistor layers during formation, and to provide a better lattice match between the collector material (e.g., InGaAsSb) and the substrate material (e.g., GaSb or InGaSb). The buffer laurel also selves to absorb at least some defects that might otherwise penetrate the collector layer from the substrate and effectively reduce the crystal quality of the overall device.

Like the other layers of the phototransistor according to the present invention, the at least one buffer layer, if included, preferably comprises antimony. Preferably, the material of the or each buffer layer is selected from the group consisting of GaSb, InGaSb, InGaAsSb, Al(In)GaAsSb and AlGaSb. The composition of the or each buffer layer is preferably selected depending upon the compositions of the other components of the phototransistor.

The or each buffer layer, if included, preferably has a thickness in a range of from about 100 nanometers to about 3 micrometers.

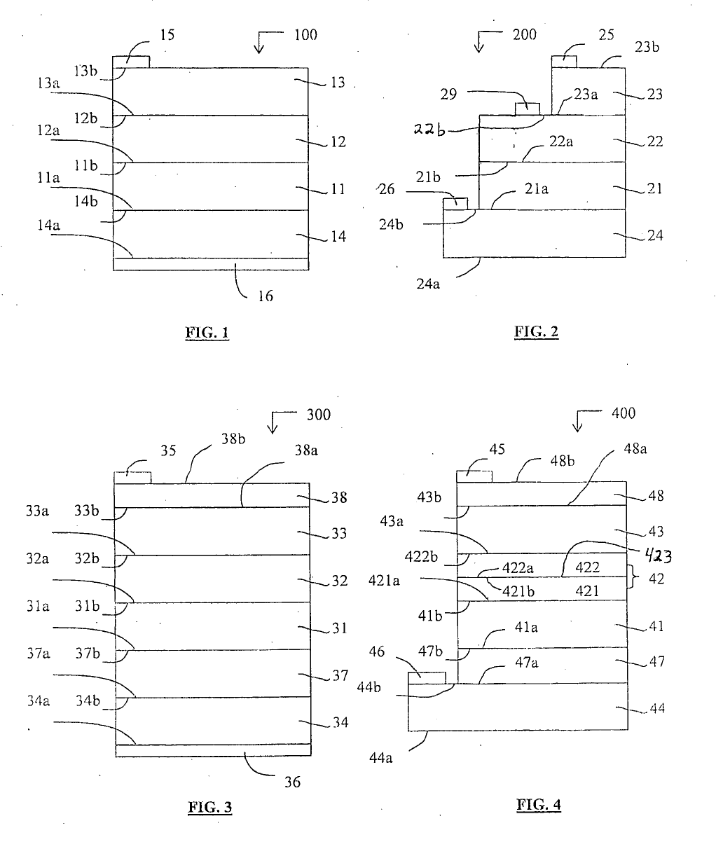

As mentioned above, the phototransistors according to the present invention can optionally further comprise at least one contact layer which is positioned on the emitter, as shown and described below in connection with FIGS. 2 and 3. The one or more contact layer, if included, serves to reduce possible negative effects resulting from the tendency of aluminum (if contained in the emitter) to react with oxygen, which often results in the formation of a thick oxidized layer on the emitter where the contact is to be formed.

The or each contact layer, if included, preferably comprises antimony. Examples of suitable materials out of which the or each contact layer can be formed include (and are not limited to) GaSb, InGaSb, TIGaAsSb, Al(in)GaAsSb and AlGaSb.

The or each contact layer, if included, preferably has a thickness in a range of from about 10 nanometers to about 1 micrometer.

The phototransistors according to the present invention preferably each further comprises at least one front contact and at least one back contact. The at least one conductive front contact, if included, is preferably positioned on at least a portion of the emitter on a side which is opposite the base (or, if one or more contact layer is included, on at least a portion of a contact layer on a side which is opposite the base). The at least one conductive back contact, if included, is preferably positioned on at least a portion of the substrate on a side which is opposite the collector. Optionally, a base contact can be provided in contact with a portion of the base.

The first conductive contact member preferably comprises an annular ohmic front side contact formed on the emitter (or, if present, a contact layer) and the second conductive contact preferably comprises a planar conductive contact formed on a backside of the substrate. Suitable materials for each of the conductive contact members include (and are not limited to) Ti—Ni—Au, Ti—Pd—Ag, Au—Sn, Pd—Ge—Au, Pd—Ge—Pd, Au—Ge, preferably formed by an electron-beam evaporation techniques, such techniques being well known in the art

As discussed above, in a first aspect of the present invention, the base comprises a composite material having a plurality of different bandgap values such that there is an overall bandgap gradient between the emitter-contacting portion of the base and the collector-contacting portion of the base, with the bandgap values decreasing as the distance from the emitter-contacting portion of the base increases and the distance from the base collector-contacting portion decreases. In such a phototransistor, the bandgap value of the emitter is preferably larger than the bandgap value of the base at the emitter-contacting portion of the base, to provide a p-n heterojunction at the emitter-base interface, and/or the collector bandgap value is preferably less than the bandgap value of the base at the collector-contacting portion of the base to provide a p-n heterojuniction at the base-collector interface.

As discussed above, in a second aspect of the present invention, the base comprises at least a first base layer and a second base layer, in which the first base layer includes the emitter-contacting portion of the base and comprises a first band gap value, and in which the second base layer includes the collector-contacting portion of the base and comprises a second bandgap value that is less than the first bandgap value. Preferably, the first and second base layers provide a p-p heterojunction at the first-second base layer interface due to a difference in their respective bandgaps. Optionally, the emitter can comprise a bandgap value which is larger than the first bandgap value in order to provide a p-n heterojunction at the emitter-base interface, and/or the collector can comprise a bandgap value which is less than the second bandgap value in order to provide a p-n heterojunction at the base-collector interface. In this aspect of the present invention, preferably, the first base layer preferably consists essentially of AlGaAsSb, and the second base layer preferably consists essentially of InGaAsSb.

According to a third aspect. of the present invention, the emitter-contacting portion of the base comprises a bandgap value which is less than a bandgap value of the base-contacting portion of the emitter in order to provide a p-n heterojunction at the emitter-base interface, and/or the base-contacting portion of the collector comprises a handgap which is less than a bandgap of the collector-contacting portion of the base in order to provide a heterojunction at the collector-base interface. In this aspect of the present invention, the base preferably has a substantially uniform bandgap, although the bandgap of the base may alternatively vary to some degree.

According to a fourth aspect of the present invention, the emitter-contacting portion of the base comprises a bandgap value which is less than a bandgap value of the base-contacting portion of the emitter in order to provide a p-n heterojunction at the emitter-base interface, and/or the base-contacting portion of the collector comprises a bandgap which is substantially equal to a bandgap of the collector-contacting portion of the base in order to provide a homojunction at the collector-base interface. In this aspect of the present invention, the base preferably has a substantially uniform bandgap, although the bandgap of the base may alternatively vary to some degree.

According to a fifth aspect of the present invention, the emitter-contacting portion of the base comprises a bandgap value which is less than a bandgap value of the base-contacting portion of the emitter in order to provide a p-n heterojunction at the emitter-base interface, and/or the base-contacting portion of the collector comprises a bandgap which is greater than a bandgap of the collector-contacting portion of the base in order to provide a heterojunction at the collector-base interface. In this aspect of the present invention, the base preferably has a substantially uniform bandgap, although the bandgap of the base may alternatively vary to some degree. If a substrate is present, typically, there is a heterojunction between the substrate and the collector (or, if a buffer layer is included, between the substrate and a buffer layer and/or between a buffer layer and the collector, and/or, if more than one buffer layers are included, between any two buffer layers).

Preferably, the lower bandgap material (e.g., at least a portion of the collector or, in some cases, at least a portion of the base) in the phototransistors of the present invention have bandgap values in the range of from about 0.5 eV to about 0.7 eV.

Preferably, the emitter has the largest bandgap value of the phototransistor. The collector can have a larger bandgap value than the base-such a feature would increase the speed of the phototransistor.

The collector, the base and the emitter, as well as any buffer layer(s) and/or any contact layer(s), are preferably deposited on the substrate sequentially, in the order of their distance from the substrate, i.e., first any buffer layer(s), if present, then the collector, then the base (in the second aspect of the invention, the base layers are preferably deposited sequentially), and then the emitter, followed by any contact layer(s), if present.

Preferably, the collector, the base and the emitter, as well as any buffer layer(s) and/or any contact layer(s), are each deposited epitaxially according to at least one of a variety of well-known semiconductor formation techniques. Suitable examples of such techniques include (and are not limited to), liquid phase epitaxy (LPE) processes, molecular beam epitaxy (MBE) processes and metal-organic chemical vapor deposition (MOCVD) processes, each of which are well known in the art, as well as combinations of such techniques. Preferably, the collector, the base and the emitter, as well as any buffer layer(s) and/or any contact layer(s) are deposited using a single technique, but alternatively, different components of the phototransistor can be formed by different techniques, and/or individual components can be formed by a combination of more than one technique and/or by different techniques performed sequentially.

In order to provide a higher crystal quality and to reduce the potential for defect formation (which would enable minority carriers in the phototransistor layers to have a longer diffusion length), the emitter, the base and the collector (and, if present, any buffer layer(s) and/or any contact layer(s)) are preferably substantially lattice matched to the substrate. Persons of skill in the art are abundantly familiar with altering the composition of materials from which the depositing material comes (e.g., in the case of CVD, altering the composition of the surrounding gases), in order to provide the different components while minimizing lattice mismatch and minimizing the likelihood for defects to be formed in the crystal structure.

In order to provide desired bandgap values at each location within each of the components of the phototransistors of the present invention, the composition of materials from which the depositing material comes is altered, according to techniques which are well known in the art.

Optimum bandgap values depend on several considerations, in particular the application for which the phototransistor is going to be applied. That is, optimum bandgap values would differ between a case where it is desired that the phototransistor detect only light at a particular wavelength, e.g., 2.0 micrometers (and where all other wavelengths are considered to be parasitic) vs. a case where it is desired that the phototransistor should detect all wavelengths within a range of values, and persons of skill in the art are familiar with how such considerations would affect the desired bandgap values at various positions of the phototransistor, as well as how to provide such bandgap values.

In addition, in each case, the material being deposited during the formation of the collector, the base and the emitter is appropriately doped according to standard procedures which are well known in the art, in order to provide an n-type collector, a p-type base and an n-type emitter (where an n-p-n phototransistor is being made), or a p-type collector, an n-type base and a p-type emitter (where a p-n-p phototransistor is being made). In addition, persons of skill in the art are familiar with making decisions as to amounts of dopant to be used in various regions of phototransistors in order to optimize the functionality of the phototransistor (e.g., to provide the desired trade-off between speed and internal gain).

In cases where the components comprise group III elements and group V elements, e.g., As, Sb, In, Al and Ga, preferably, the overall ratio of Group V elements (e.g., As and Sb) to Group III elements (e.g., In, Al and Ga) preferably remains about 50:50 throughout the entire forming process.

Referring now to the drawings, FIG. 1 is a schematic view of a first embodiment of a phototransistor according to the present invention. FIG. 1 depicts a phototransistor 100 which includes a substrate 14, a collector 11 in contact with the substrate 14, a base 12 in contact with the collector 11, and an emitter 13 in contact with the base 12. The substrate 14 has a collector-contacting surface 14b and an opposite surface 14a in contact with a hack conductive contact member 16. The collector 11 has a substrate-contacting surface 11a and an opposite base-contacting surface 11b. The base 12 has a collector-contacting surface 12a and an opposite emitter-contacting surface 12b. The emitter 13 has a base-contacting surface 13a and an opposite surface 13b in contact with a front conductive contact member 15.

In phototransistor 100, back conductive contact member 16 substantially covers the entire surface 14a of substrate 14. The phototransistor 100 could alternatively include a conductive contact member arrangement as shown and described below in connection with the structure of the phototransistor 400 shown in FIG. 4. Buffer layers and/or contact layers, depicted in the embodiments shown in FIGS. 3 and 4 with reference numbers 37, 47 and 38, 48, respectively, could be included in the phototransistor 100.

FIG. 2 is a schematic view of a second embodiment of a phototransistor according to the present invention. FIG. 2 depicts a phototransistor 100 which includes a substrate 24, a collector 21 in contact with the substrate 24, a base 22 in contact with the collector 21, and an emitter 23 in contact with the base 22. The substrate 24 has a collector-contacting surface 24b and an opposite surface 24a in contact with a back conductive contact member 26. The collector 21 has a substrate-contacting surface 21a and an opposite base contacting surface 21b. The base 22 has a collector-contacting surface 22a and an opposite emitter-contacting surface 22b, and the emitter 23 has a base-contacting surface 23a and an opposite surface 23b in contact with a front conductive contact member 25.

In phototransistor 200, the back conductive contact member 26 is provided in a localized position on a portion of the collector-contacting surface 24b substrate 24. Further, a third conductive contact member 29 is provided in a localized position on a portion of the emitter-contacting surface 22b of the base 22. The third conductive contact member 29 is not in contact with the emitter 23 or the conductive contact members 25 and 26. The back conductive contact member 26 of the phototransistor 200 could alternatively be provided in a manner similar to the back conductive contact member 36 of the phototransistor 300 shown in FIG. 3, described below. Buffer layers and/or contact layers, depicted in the embodiments shown in FIGS. 3 and 4 with reference numbers 37, 47 and 38, 48, respectively, could be included in the phototransistor 200.

FIG. 3 is a schematic view of a third embodiment of a phototransistor according to the present invention. FIG. 3 depicts a phototransistor 300 which corresponds to the first aspect of the present invention, as described above. The phototransistor 300 includes a substrate 34, a buffer layer 37 in contact with the substrate 34, a collector 31 in contact with the buffer layer 37, a base 32 in contact with the collector 31, an emitter 33 in contact with the base 32, a contact layer 38 in contact with the emitter 33, a front conductive contact member 35 in contact with the contact layer 38 and a back conductive contact member 36 in contact with the substrate 34.

The base 32 comprises a composite material having a plurality of different bandgap values such that there is an overall bandgap gradient between the emitter-contacting portion 32b of the base 32 and the collector-contacting portion 32a of the base 32, with the bandgap values decreasing as the distance from the emitter-contacting portion 32b increases and the distance from the base collector-contacting portion 32a decreases.

The substrate 34 has a buffer layer-contacting surface 34b and an opposite surface 34a in contact with the back conductive contact member 36. The buffer layer 37 has a substrate-contacting surface 37a and an opposite collector-contacting surface 37b. The collector 31 has a buffer layer-contacting surface 31a and an opposite base-contacting surface 31b. The base 32 has a collector-contacting surface 32a and an opposite emitter-contacting surface 32b. The emitter 33 has a base-contacting surface 33a and an opposite contact layer-contacting surface 33b. The contact layer 38 has an emitter-contacting surface 38a and an opposite surface 38b in contact with the front conductive contact member 35.

Similar to the phototransistor 100, the back conductive contact member 36 of the phototransistor 300 substantially covers the entire surface 34a of the substrate 34. The back conductive contact member 36 of the phototransistor 300 could alternatively be provided in a manner similar to the back conductive contact member 46 of the phototransistor 400 shown in FIG. 4, described below.

FIG. 4 is a schematic view of a fourth embodiment of a phototransistor according to the present invention. FIG. 4 depicts a phototransistor 400 which corresponds to the second aspect of the present invention, as described above. The phototransistor 400 includes a substrate 44, a buffer layer 47 in contact with the substrate 44, a collector 41 in contact with the buffer layer 47, a base 42 in contact with the collector 41, an emitter 43 in contact with the base 42, a contact layer 48 in contact with the emitter 43, a front conductive contact member 45 in contact with the contact layer 48 and a back conductive contact member 46 in contact with the substrate 44.

The base 42 of the phototransistor 400 includes a first base layer 422 and a second base layer 421, a base layer interface 423 being defined between the first and second base layers 421, 422. The second base layer 421 is in contact with the collector 42 and with the first base layer 422, and the first base layer 422 is in contact with the second base layer 421 and with the emitter 43.

Substrate 44 has a buffer layer-contacting surface 44b and an opposite surface 44a. The back conductive contact member 46 is in contact with a portion of the buffer layer-contacting surface 44b which is not covered by the buffer layer 47. The buffer layer 47 has a substrate-contacting surface 47a and an opposite collector-contacting surface 47b. The collector 41 has a buffer layer-contacting surface 41a and an opposite second base layer-contacting surface 41b. The second base layer 421 has a collector-contacting surface 421a and an opposite surface 421b. The first base layer 422 has a first base layer-contacting surface 422a and an opposite emitter-contacting surface 422b. The emitter 43 has a first base layer-contacting surface 43a and an opposite contact layer-contacting surface 43b. The contact layer 48 has an emitter-contacting surface 48a and an opposite surface 48b. The front conductive contact member 45 is in contact with a portion of the surface 48b of the contact layer 48.

The first base layer 422 comprises a first band gap value, and the second base layer 421 comprises a second bandgap value that is less than the first bandgap value. The first and second base layers provide a p-p heterojunction at the first-second base layer interface 423 due to the difference in their respective bandgaps.

The emitter 43 comprises a bandgap value which is larger than the first bandgap value in order to provide a p-n heterojunction at the interface between the emitter 43 and the first base layer 422 of the base 42. Alternatively, the emitter 43 could instead comprise a bandgap value which is substantially equal to the first bandgap value such that there is not a p-n heterojunction (a p-n homojunction exists) at the interface between the emitter 43 and the first base layer 422 of the base 42.

The collector 41 comprises a bandgap value which is less than the second bandgap value in order to provide a p-n heterojunction at the interface between the second base layer 421 of the base 42 and the collector 41. Alternatively, the collector 41 could instead comprise a bandgap value which is substantially equal to the second bandgap value such that there would not be a p-n heterojunction at the interface between the second base layer 421 of the base 42 and the collector 41. Alternatively, the collector 41 could comprise a bandgap value which is larger than the second bandgap value in order to provide a p-n heterojunction at the interface between the second base layer 421 of the base 42 and the collector 41.

Like the phototransistor 200, the back conductive contact member 46 is provided in a localized position on a portion of the buffer layer-contacting surface 44b of the substrate 44 such that the back conductive contact 46 is not in contact with the buffer-layer 47. The back conductive contact 46 of the phototransistor 400 could alternately be provided in a similar manner to the back conductive contact 36 of the phototransistor 300 shown in FIG. 3.

### EXAMPLE

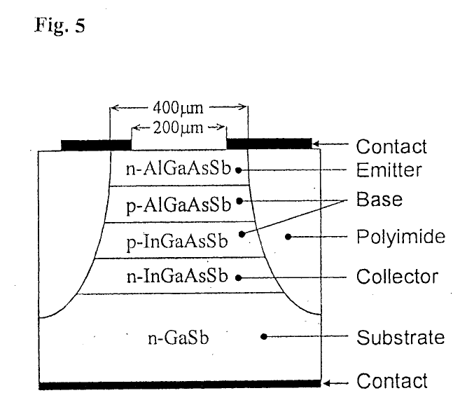

A device according to the present invention was constructed to he as depicted in FIG. 5. The device according to the present invention used in this Example includes an n-type AlGaAsSb emitter, a p-type composite base consisting of AlGaAsSb and InGaAsSb layers, and an n-type InGaAsSb collector. The collector, the base and the emitter were all lattice-matched to a GaSb substrate and were grown by liquid-phase epitaxy using a horizontal slideboat technique. The bandgap energies of the AlGaAsSb and InGaAsSb layers are 1-1.1 eV and 0.55 eV, respectively, as estimated from chemical composition and spectral response measurements. Mesa phototransistors with a 400 μm diameter total area and a 200 μm diameter active area were defined using photolithography and wet chemical etching. A backside planar and a front side annular ohmic contact, including a bonding pad, were deposited by electron beam evaporation of Au/Sn and Ti/Ni/Au, respectively. A polyimide coating (HD Microsystems PI-2723 photodefinable polyimide resin) was spun on the front of the device. The polyimide serves several functions, including planarization of the top surface, mesa isolation and edge passivation. After dicing, 1 mm² pieces with a single device in the middle of each square were mounted onto TO-18 headers using silver conducting epoxy, and the pieces were wire-bonded to the headers. No antireflection coatings were applied.

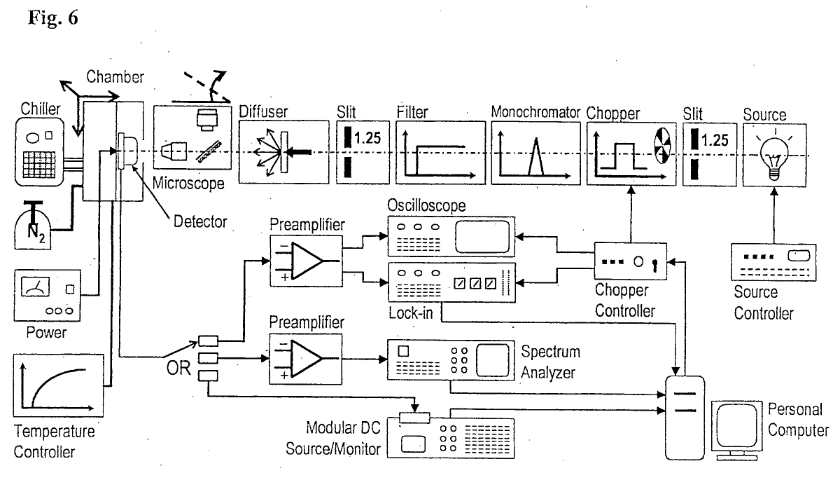

Several prototype InGaAsSb/AlGaAsSb phototransistors were fabricated and characterized in order to compare their performance with existing 2-μm detector technologies in areas other than the requirement of the CO₂ DIAL measurements. The characterization experiments included emitter dark current, responsivity and noise measurements. FIG. 6 depicts the experimental setup used to obtain these characteristics. The setup is divided mainly into optical, electrical and detector control sections. The optical section is used to apply a uniform, monochromatic radiation onto the detector, with known intensity. The electrical section mainly measures the detector output, corresponding to certain operating conditions, while maintaining these conditions using the detector control section.

In the optical section, the radiation source consists of a current controlled quartz halogen lamp, the output of which is modulated using an optical chopper. The chopping frequency is set to 167 Hz to reduce the effect of pickup noise. A monochromator is used to separate the radiation into its spectral components with a 20 nm n resolution as set by the input/output slits and the grating. Higher order dispersion of the shorter wavelength is blocked using appropriate high-pass filters, while a diffuser is mounted at about 10 cm from the detector to insure radiation uniformity. An optical microscope was used to set the location of the optical axis and to fix the distance between the radiation source and the sensitive area of the detector. The radiation uniformity is estimated to be less than 1% along a 15 mm² area at the detector location.

The detector output current is converted into voltage signal using the pre-amplifier (Stanford Research Systems; SR570), the output of which is applied to a lock-in amplifier (Optronic Laboratories, Inc.; OL 750-C), oscilloscope (Agilent; infiniium) or spectrum analyzer (Stanford Research Systems; SR785) for responsivity and noise measurements. For emitter dark current measurements, a modular dc source/monitor (Hewlett Packard; 4142B) is connected directly to the detector. The chopper controller synchronizes the applied optical signal, if any, with the data acquisition device through the personal computer.

The detector is mounted inside a chamber that controls its temperature and provides mechanical support. For high temperature operation down to −23° C., an open chamber is used. In the open chamber, the temperature is controlled using thermoelectric coolers and a thermistor, located as close as possible to the device. Water circulation through a chiller removes excess heat accumulation and nitrogen purging prevents water condensation and ice formation on the detector surface at temperatures below 0° C. For lower temperature operation, a cryogenic chamber is used with liquid nitrogen as the cooling media, with vacuum isolation and a controlled resistive heater to set the temperature. To bias the detector, the pre-amplifier is used for voltages in the 0 to 4 V range while the external de power supply is used for higher voltages. Mechanical mount allows detector alignment within 10 μm resolution.

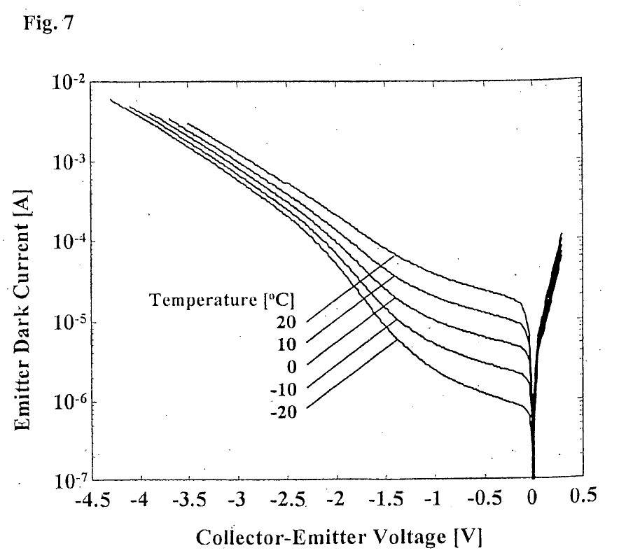

The emitter dark current variation with the collector-emitter voltage at different temperatures is depicted in FIG. 7. Emitter dark current was obtained by 1-V measurements in dark conditions by applying the bias voltage to the emitter while the collector contact connected to the ground. Two current regions were observed in these characteristics. In the first region, where 0- to 1.5-V was applied, there is a relatively low current with strong temperature dependence. At higher voltage, above 1.5 V, a sharp increase in the dark current with lower temperature dependence and high current-voltage linearity is observed. Emitter dark current measurements reveal the absence of any avalanche gain.

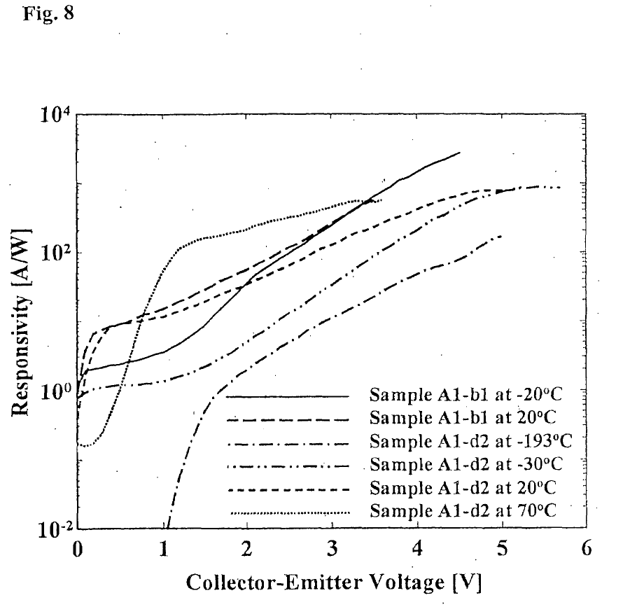

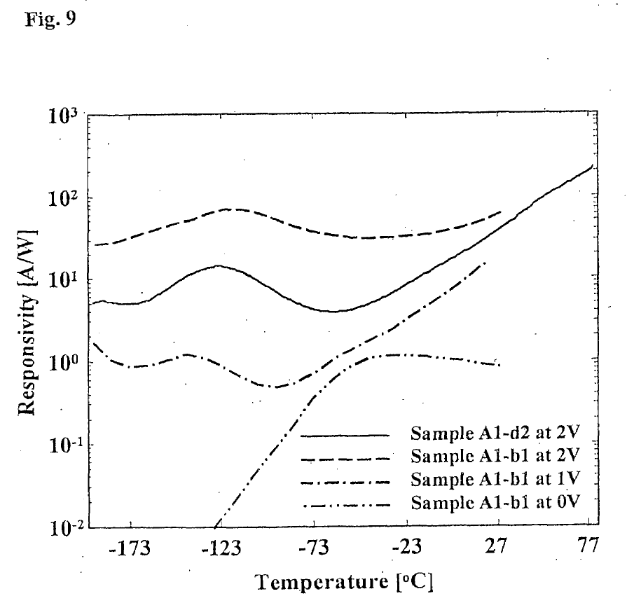

The device spectral response peaks around the 2-μm wavelength, which is optimal for CO₂ measurements. Therefore, responsivity variation with bias voltage and temperature are presented at 2.05 μm. At this particular wavelength, a strong CO₂ absorption line exists with minimal influence from other species, such as water vapor. FIG. 8 depicts the responsivity variation with the collector-emitter voltage at different temperatures for two phototransistor samples (A1-b1 and A1-d2). As a general trend, a sharp increase in the responsivity at lower bias voltage is observed, followed by a knee and then saturation at higher voltage. FIG. 9 depicts the responsivity variation with temperature at different collector-emitter voltages for the same samples. The results indicate complicated temperature dependence, and some additional studies are required to explain its peculiarities. Responsivity as high as 2650 A/W, corresponding to an internal gain of 2737, was measured with phototransistor A1-b1 at 2.05 μm, −20° C. and 4.5 V.

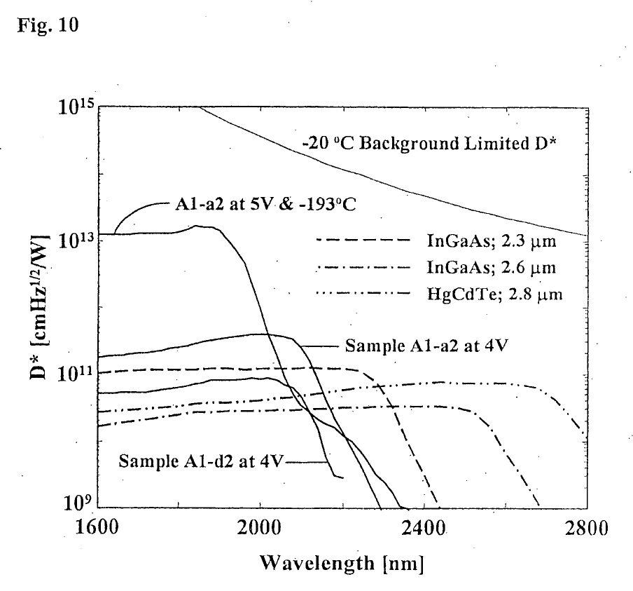

FIG. 10 depicts the detectivity calculation of two phototransistors (samples A1-d2 and A1-a2) as compared to the state-of-the-art, 1 mm diameter InGaAs and HgCdTe photodiodes, listed in Table 1. Detectivity calculation was obtained using noise measurements in the dark conditions and spectral response data. FIG. 10 also compares the results with the ideal background limited detectivity, assuming black body source at −20° C., with 118° detector field-of-view. All results obtained at −20° C., and -193° C. were considered only for A1-a2 sample to emphasize cooling improvements. Cooling down the device reduces the dark current, which allows for higher voltage operation and hence, increases the responsivity. Besides, cooling reduces the dark noise leading to increase the detectivity for shorter wavelength. For the shown curve, the peak detectivity of 1.6×10¹³ cm·Hz¹/2/W was shifted to 1.85-μm at 5.0 V bias. The operating bias voltage for the commercial detectors was 1 V as specified by the manufacturer. Increasing the bias voltage for the commercial detectors significantly increases the noise, leading to detectivity deterioration.

TABLE 1

| Material | Manufacturer | Part # | Structure | Cut-off |
|---|---|---|---|---|
| InGaAs | Hamamatsu | G5852 | pin | 2.3 micrometers |
| InGaAs | Hamamatsu | G5853 | pin | 2.6 micrometers |
| HgCdTe | Judson | J19:2.8-18C- | pin | 2.8 micrometers |
| | | R01M | | |

In summary, in the range of typical terrestrial temperatures and at bias voltages exceeding several tenths of volt, increase of responsivity both with temperature and voltage is observed. The phototransistor of the present invention showed superior detectivity compared to standard InGaAs and HgCdTe photodetectors. With relatively low dark current and high responsivity, signal-to-noise ratio improvements meet the requirement of the CO₂ measurement using the DIAL technique.

What is claimed is:

1. A phototransistor, comprising:
an emitter comprising antimony;
a base comprising antimony, said base comprising an emitter-contacting portion which is in contact with a base-contacting portion of said emitter; and
a collector comprising antimony, said collector comprising a base-contacting portion which is in contact with a collector-contacting portion of said base,
said phototransistor producing an internal gain upon being contacted with light within a receivable wavelength range.

2. A phototransistor as recited in claim 1, wherein said emitter, said base and said collector are each substantially lattice-matched.

3. A phototransistor as recited in claim 1, wherein said emitter comprises at least one material selected from the group consisting of AlInGaAsSb, AlGaAsSb, InGaAsSb, AlGaSb and GaSb.

4. A phototransistor as recited in claim 1, wherein said base comprises AlInGaAsSb, AlGaAsSb, InGaAsSb, AlGaSb and GaSb.

5. A phototransistor as recited in claim 1, wherein said collector comprises AlInGaAsSb, AlGaAsSb, InGaAsSb, AlGaSb and GaSb.

6. A phototransistor as recited in claim 1, wherein said base comprises a bandgap gradient defined between said emitter-contacting portion and said collector-contacting portion thereof, said base bandgap gradient comprising a plurality of base bandgap values that decrease in a direction away from said emitter-contacting portion and toward said collector-contacting portion.

7. A phototransistor as recited in claim 6, wherein a bandgap value at said base-contacting portion of said emitter is greater than or substantially equal to a bandgap value at said emitter-contacting portion of said base, and wherein a bandgap value at said base contacting portion of said collector is less than or substantially equal to a bandgap value at said collector-contacting portion of said base.

8. The phototransistor according to claim 7, wherein said bandgap value at said base-contacting portion of said emitter is greater than said bandgap value at said emitter-contacting portion of said base.

9. The phototransistor according to claim 7, wherein said bandgap value at said base-contacting portion of said collector is less than said bandgap value at said collector-contacting portion of said base.

10. A phototransistor as recited in claim 1, wherein said base comprises at least a first base layer and a second base layer, said first base layer including said emitter-contacting portion and comprising a first band gap value, said second base layer including said collector-contacting portion and comprising a second bandgap value, said first bandgap value being greater than said second bandgap value.

11. A phototransistor as recited in claim 10, wherein said first base layer consists essentially of at least one material selected from the group consisting of AlGaAsSb and AlInGaAsSb.

12. A phototransistor as recited in claim 10, wherein said second base layer consists essentially of InGaAsSb.

13. A phototransistor as recited in claim 10, wherein said emitter comprises a bandgap value which is larger than or substantially equal to said first bandgap value.

14. A phototransistor as recited in claim 10, wherein said collector comprises a bandgap value which is less than or substantially equal to said second bandgap value.

15. A phototransistor as recited in claim 1, wherein said emitter comprises an emitter bandgap value, said base comprises a base bandgap value and said collector comprises a collector bandgap value, wherein said emitter bandgap value is greater than or substantially equal to said base bandgap value, and wherein said base bandgap value is greater than or substantially equal to said collector bandgap value.

16. A phototransistor as recited in claim 15, wherein said emitter bandgap value is greater than said base bandgap value.

17. A phototransistor as recited in claim 16, wherein said base bandgap value is substantially equal to said collector bandgap value.

18. A phototransistor as recited in claim 16, wherein said collector bandgap value is greater than said base bandgap value

19. A phototransistor as recited in claim 1, wherein said emitter-contacting portion of said base comprises a first bandgap value and said base-contacting portion of said emitter comprises a second bandgap value, said first bandgap value being less than said second bandgap value.

20. A phototransistor as recited in claim 19, wherein said collector-contacting portion of said base has a third bandgap value, said second bandgap value being less than said third bandgap value.

21. A phototransistor as recited in claim 19, wherein said collector-contacting portion of said base has a third bandgap value, said second bandgap value being substantially equal to said third bandgap value.

22. A phototransistor as recited in claim 19, wherein said collector-contacting portion of said base has a third bandgap value, said second bandgap value being greater than said third bandgap value.

23. A phototransistor as recited in claim 1, further comprising a substrate.

24. A phototransistor as recited in claim 23, wherein said substrate comprises antimony.

25. A phototransistor as recited in claim 24, wherein said substrate consists essentially of GaSb or InGaSb.

26. A phototransistor as recited in claim 23, wherein said substrate, said collector, said base and said emitter are substantially lattice matched.

27. A phototransistor as recited in claim 1, wherein said emitter, said base and said collector together comprise an n-p-n transistor.

28. A phototransistor as recited in claim 1, wherein said emitter, said base and said collector together comprise a p-n-p transistor.

29. A phototransistor as recited in claim 1, wherein said receivable wavelength range is from 1.8 micrometers to 2.5 micrometers.

30. A phototransistor that produces an internal gain upon being contacted with light within a receivable wavelength range, said phototransistor comprising:
a substrate comprising antimony;
a collector comprising antimony, said collector comprising a substrate-contacting portion which is in contact with a collector-contacting portion of said substrate;
a base comprising antimony, said base comprising a collector-contacting portion which is in contact with a base-contacting portion of said collector; and
an emitter comprising antimony, said emitter comprising a base-contacting portion which is in contact with an emitter-contacting portion of said base;
wherein said substrate, said collector, said base and said emitter are each substantially lattice matched.

31. A phototransistor that produces an internal gain upon being contacted with light within a receivable wavelength range, said phototransistor comprising:
a substrate comprising antimony;
a collector comprising antimony, said collector comprising a substrate-contacting portion which is in contact with a collector-contacting portion of said substrate;
a base comprising antimony, said base comprising a collector-contacting portion which is in contact with a base-contacting portion of said collector; and
an emitter comprising antimony, said emitter comprising a base-contacting portion which is in contact with an emitter-contacting portion of said base, said phototransistor being formed by a method comprising:
forming said collector on said substrate using a process such that said collector is substantially lattice matched to said substrate;
forming said base on said collector using a process such that said base is substantially lattice matched to said collector; and
forming said emitter on said base using a process such that said emitter is substantially lattice matched to said base.

32. A phototransistor as recited in claim 31, wherein said process comprises at least one process selected from the group consisting of liquid phase epitaxy processes, molecular beam epitaxy processes, and metal-organic chemical vapor deposition processes.

33. A method of forming a phototransistor that produces an internal gain upon being contacted with light within a receivable wavelength range, said method comprising:
forming a collector comprising antimony on a substrate comprising antimony using a process such that said collector is substantially lattice matched to said substrate;
forming a base comprising antimony and having a collector-contacting portion in contact with a base-contacting portion of said collector using a process such that said base is substantially lattice matched to said collector; and
forming an emitter comprising antimony and having a base-contacting portion in contact with an emitter-contacting portion of said base using a process such that said emitter is substantially lattice matched to said base.

34. A method as recited in claim 33, wherein said process comprises at least one process selected from the group consisting of liquid phase epitaxy processes, molecular beam epitaxy processes, and metal-organic chemical vapor deposition processes.

35. A method as recited in claim 33, further comprising:
forming a buffer layer comprising antimony on said substrate such that said buffer layer is positioned between said substrate and said collector.

36. A method as recited in claim 33, further comprising:
forming a contact layer comprising antimony on a portion of said emitter opposite said base-contacting portion of said emitter.

37. A method as recited in claim 36, further comprising forming a first conductive member on a portion of said contact layer opposite an emitter-contacting portion of said contact layer and forming a second conductive member on a portion of said substrate opposite said portion of said substrate on which said buffer layer is formed.

38. A method as recited in claim 37, further comprising forming a third conductive member in contact with said base.

39. A method as recited in claim 33, further comprising forming a first conductive member on a portion of said emitter opposite said base-contacting portion of said en-litter and forming a second conductive member on a portion of said substrate opposite said portion of said substrate on which said collector is formed.

40. A method as recited in claim 39, further comprising forming a third conductive member in contact with a portion of said base.

41. A method as recited in claim 33, wherein said forming said base comprises forming a bandgap gradient which increases from said collector-contacting portion of said base toward said emitter-contacting portion of said base.

42. A method as recited in claim 33, wherein said forming said base comprises forming a second base layer in contact with said collector and forming a first base layer in contact with said second base layer, said first base layer including said emitter-contacting portion and comprising a first band gap value, said second base layer including said collector-contacting portion and comprising a second bandgap value, said first bandgap value being greater than said second bandgap value.

43. A method as recited in claim 33, wherein said substrate comprises GaSb.

44. A method as recited in claim 33, wherein said collector comprises InGaAsSb.

45. A method as recited in claim 33, wherein said base comprises at least one of AlGaAsSb and InGaAsSb.

46. A method as recited in claim 33, wherein said emitter comprises AlGaAsSb.

47. A method as recited in claim 42, wherein said first base layer comprises AlGaAsSb and said second base layer comprises InGaAsSb.

48. A method of detecting light, comprising contacting a phototransistor as recited in claim 1 with light comprising at least a first wavelength, said first wavelength falling within said receivable wavelength range, and applying a current through said phototransistor, said current being amplified as a result of said light contacting said phototransistor.

49. A method as recited in claim 48, wherein said light comprises infrared light.
